(19) United States
(12) Patent Application Publication
(10) Pub. No.: US 2011/0230008 A1
(43) Pub. Date: Sep. 22, 2011

(54) Method and Apparatus for Silicon Film Deposition

(75) Inventors: Annamalai Lakshmanan, Fremont, CA (US); Truc T. Tran, Fremont, CA (US); Jeffrey S. Sullivan, Castro Valley, CA (US); Jianshe Tang, San Jose, CA (US)

(73) Assignee: Applied Materials, Inc., Santa Clara, CA (US)

(21) Appl. No.: 12/773,497

(22) Filed: May 4, 2010

(30) Foreign Application Priority Data
Mar. 17, 2010 (CN) PCT/CN2010/000325

(51) Int. Cl. H01L 31/18

(52) U.S. Cl. 438/96; 118/722; 118/723 R; 257/E31.001

(57) ABSTRACT

Embodiments of the present invention are directed to apparatus and methods for depositing amorphous and microcrystalline silicon films during the formation of solar cells. Specifically, embodiments of the invention provide for a pre-heated hydrogen-containing gas to be introduced into a processing chamber separately from the silicon-containing gas. A plasma, struck from the heated hydrogen-containing gas, reacts with the silicon-containing gas to produce a silicon film on a substrate.

### CROSS-REFERENCE TO RELATED APPLICATIONS

This application claim priority under 35 U.S.C.§119(a) to PCT International Application No. PCT/CN2010/000325, filed Mar. 17, 2010, the disclosure of which is hereby incorporated herein in its entirety.

### BACKGROUND

Embodiments of the invention relate to an apparatus and method for forming solar cells. More particularly, embodiments of the present invention relate to an apparatus and method for forming amorphous and microcrystalline silicon layers utilized in solar cell applications.

Photovoltaic (PV) devices or solar cells are devices which convert sunlight into direct current (DC) electrical power. Typical thin film PV devices, or thin film solar cells, have one or more p-i-n junctions. Each p-i-n junction comprises a p-type layer, an intrinsic type layer, and an n-type layer. When the p-i-n junction of the solar cell is exposed to sunlight (consisting of energy from photons), the sunlight is converted to electricity through the PV effect. Solar cells may be tiled into larger solar arrays.

Typically, a thin film solar cell includes active regions, or photoelectric conversion units, and a transparent conductive oxide (TCO) film disposed as a front electrode and/or as a back electrode. The photoelectric conversion unit includes a p-type silicon layer, an n-type silicon layer, and an intrinsic type (i-type) silicon layer sandwiched between the p-type and n-type silicon layers. Several types of silicon films including microcrystalline silicon film (μc-Si), amorphous silicon film (a-Si), polycrystalline silicon film (poly-Si), and the like may be utilized to form the p-type, n-type, and/or i-type layers of the photoelectric conversion unit. The backside electrode may contain one or more conductive layers.

Both amorphous and microcrystalline silicon films are currently being used to form solar cells. However, problems exist in current production equipment and methods used in the deposition of these films. For example, in conventional thermal chemical vapor deposition and plasma enhanced chemical vapor deposition (PECVD) processes, the low energy gas phase combination of silicon and hydrogen leads to the formation of polymerized silicon and hydrogen structures, which can lead to particle generation, inefficient film deposition, and physically and electrically inferior and unstable deposited films.

Therefore, there is a need for an improved apparatus and method for depositing amorphous and microcrystalline silicon films.

### SUMMARY

One or more aspects of the invention are directed to methods for depositing a silicon film on a substrate. A hydrogen-containing gas is heated and delivered into a plasma generation region to energize the hydrogen-containing gas to generate hydrogen radicals for use in a processing region of a processing chamber. The processing region being defined as a space between a showerhead, the substrate and walls of the processing chamber. A silicon-containing gas is introduced into the processing region of the processing chamber separate from the hydrogen-containing gas to prevent mixing with the hydrogen radicals outside of the processing region of the processing chamber.

In some embodiments, the plasma generation region is in the processing region of the chamber. In some embodiments, the plasma generation region is remote from and in fluid communication with the processing region of the chamber.

Detailed embodiments further comprised monitoring the temperature of the hydrogen-containing gas. Specific embodiments further comprise heating the hydrogen-containing gas at a different rate.

In one or more embodiments, the processing region includes a substrate support. Specific embodiments further comprise delivering the silicon-containing gas from a gas source to the processing region via a plurality of gas passages within the showerhead. In detailed embodiments, the hydrogen-containing gas or hydrogen radicals are introduced to the processing region of the processing chamber through a central opening in the showerhead, the central opening being isolated from the plurality of gas passages.

In some embodiments, the hydrogen-containing gas or hydrogen radicals are introduced to the processing region of the processing chamber through an isolated line passing through the walls of the processing chamber.

According to one or more embodiments, the methods further comprise introducing one or more of trimethylboron (TMB), methane and phosphine to the processing region of the processing chamber.

Additional aspects of the invention are directed to apparatus for depositing a silicon film. The apparatus includes a processing chamber having a plurality of walls, a showerhead, and a substrate support defining a processing region within the processing chamber. The showerhead comprises a plurality of gas passages. A silicon-containing gas source is coupled to the processing region through the plurality of gas passages. A hydrogen-containing gas source is coupled to the processing region through a gas conduit. The gas conduit is thermally coupled to a heater to increase the temperature of the hydrogen-containing gas. The hydrogen-containing gas source is isolated from the silicon-containing gas source to prevent mixing of the hydrogen-containing gas and the silicon-containing gas outside of the processing region.

Some embodiments further comprise a remote plasma source in fluid communication with the gas conduit and downstream from the heater. The remote plasma source is operable to generate hydrogen radicals in the hydrogen-containing gas prior to introduction of the hydrogen-containing gas to the processing region. In detailed embodiments, the gas conduit is positioned to introduce the hydrogen-containing gas to the processing region through the chamber wall. In specific embodiments, the showerhead has a central opening in fluid communication with the gas conduit.

According to one or more embodiments, the apparatus further comprises at least one supplemental processing gas source coupled to the processing region of the processing chamber. In some embodiments, the at least one supplemental processing gas source comprises one or more of trimethylboron (TMB), methane and phosphine. In detailed embodiments, the at least one supplemental processing gas source is coupled to the processing region through the plurality of gas passages in the showerhead. Specific embodiments further comprise a proportioning valve to isolate and mix the silicon-containing gas from the at least one supplemental processing gas.

Some embodiments further comprise a temperature feedback circuit including a temperature probe coupled to the heater. The temperature feedback circuit is configured to measure the temperature of the hydrogen-containing gas and adjust the heater based on the measured temperature to control the hydrogen-containing gas temperature.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a simplified schematic diagram of a single junction amorphous silicon solar cell that may be formed, in part, using methods and apparatus according to embodiments of the present invention;

FIG. 2 is a schematic diagram of another embodiment of a multi-junction solar cell that may be formed, in part, using methods and apparatus according to embodiments of the present invention;

FIG. 3 is a schematic, cross-sectional view of a processing chamber for deposition amorphous and microcrystalline films according to one or more embodiments of the invention;

FIG. 4 is a schematic, cross-sectional view of a processing chamber for deposition amorphous and microcrystalline films according to one or more embodiments of the invention;

FIG. 5 is a schematic, cross-sectional view of a processing chamber for deposition amorphous and microcrystalline films according to one or more embodiments of the invention; and

FIG. 6 is a schematic, cross-sectional view of a processing chamber for deposition amorphous and microcrystalline films according to one or more embodiments of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally provide improved apparatus and methods for depositing amorphous and microcrystalline silicon films during the formation of solar cells. In one embodiment, a method and apparatus is provided for generating and introducing hydrogen radicals directly into a processing region of a processing chamber for reaction with a silicon-containing precursor for film deposition on a substrate. In one embodiment, the hydrogen radicals are generated by a remote plasma source and directly introduced into the processing region via a line of sight path to minimize the loss of energy by the hydrogen radicals prior to reaching the processing region. The line of sight path may include tubing formed from a non-reactive material, such as a dielectric or ceramic material. In some configurations, it is desirable to heat the tubing to reduce the possible transfer of energy to the tubing and prevent adsorption of the hydrogen radicals onto the surface of the tubing prior to introduction into the processing region.

As used in this specification and the appended claims, the term “hydrogen gas source”, “hydrogen-containing gas source” and the like are used interchangeably. A hydrogen-containing gas is a gas that, under reaction conditions, is capable of contributing hydrogen. In specific embodiments, the hydrogen-containing gas is hydrogen.

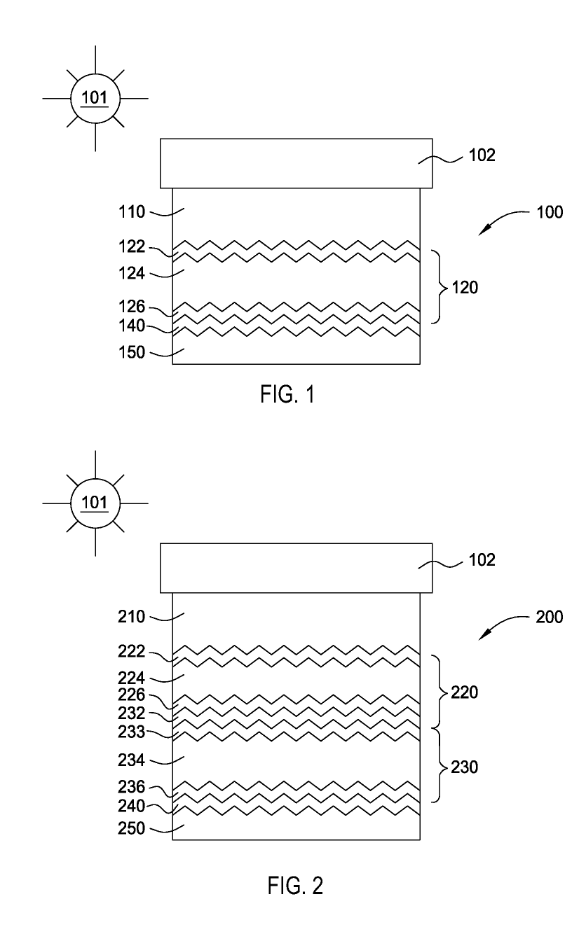

FIG. 1 is a simplified schematic diagram of a single junction amorphous silicon solar cell 100 that may be formed, in part, using methods and apparatus according to embodiments of the present invention. The single junction solar cell 100 is oriented toward a light source or solar radiation 101. The solar cell 100 generally comprises a substrate 102, such as a glass substrate, polymer substrate, metal substrate, or other suitable substrate, with thin films formed thereover. In one embodiment, the substrate 102 is a glass substrate that is about 2200 mm×2600 mm×3 mm in size. The solar cell 100 further comprises a first transparent conducting oxide (TCO) layer 110 (e.g., zinc oxide (ZnO), tin oxide (SnO)) formed over the substrate 102, a first p-i-n junction 120 formed over the first TCO layer 110, a second TCO layer 140 formed over the first p-i-n junction 120, and a back contact layer 150 formed over the second TCO layer 140.

In one configuration, the first p-i-n junction 120 may comprise a p-type amorphous silicon layer 122, an intrinsic type amorphous silicon layer 124 formed over the p-type amorphous silicon layer 122, and an n-type amorphous silicon layer 126 formed over the intrinsic type amorphous silicon layer 124. In one example, the p-type amorphous silicon layer 122 may be formed to a thickness between about 60 Å and about 300 Å, the intrinsic type amorphous silicon layer 124 may be formed to a thickness between about 1,500 Å and about 3,500 Å, and the n-type amorphous silicon layer 126 may be formed to a thickness between about 100 Å and about 500 Å. The back contact layer 150 may include, but is not limited to, aluminum (Al), silver (Ag), titanium (Ti), chromium (Cr), gold (Au), copper (Cu), platinum (Pt), alloys thereof, or combinations thereof.

FIG. 2 is a schematic diagram of an embodiment of a solar cell 200, which is a multi-junction solar cell that is oriented toward the light or solar radiation 101. The solar cell 200 comprises a substrate 102, such as a glass substrate, polymer substrate, metal substrate, or other suitable substrate, with thin films formed thereover. The solar cell 200 may further comprise a first transparent conducting oxide (TCO) layer 210 formed over the substrate 102, a first p-i-n junction 220 formed over the first TCO layer 210, a second p-i-n junction 230 formed over the first p-i-n junction 220, a second TCO layer 240 formed over the second p-i-n junction 230, and a back contact layer 250 formed over the second TCO layer 240.

The first p-i-n junction 220 may comprise a p-type amorphous silicon layer 222, an intrinsic type amorphous silicon layer 224 formed over the p-type amorphous silicon layer 222, and an n-type microcrystalline silicon layer 226 formed over the intrinsic type amorphous silicon layer 224. In one example, the p-type amorphous silicon layer 222 may be formed to a thickness between about 60 Å and about 300 Å, the intrinsic type amorphous silicon layer 224 may be formed to a thickness between about 1,500 Å and about 3,500 Å, and the n-type microcrystalline semiconductor layer 226 may be formed to a thickness between about 100 Å and about 400 Å.

The second p-i-n junction 230 may comprise a p-type microcrystalline silicon layer 232, an intrinsic type microcrystalline silicon layer 234 formed over the p-type microcrystalline silicon layer 232, and an n-type amorphous silicon layer 236 formed over the intrinsic type microcrystalline silicon layer 234. In one embodiment, prior to deposition of the intrinsic type microcrystalline silicon layer 234, an intrinsic microcrystalline silicon seed layer 233 may be formed over the p-type microcrystalline silicon layer 232. In one example, the p-type microcrystalline silicon layer 232 may be formed to a thickness between about 100 Å and about 400 Å, the intrinsic type microcrystalline silicon layer 234 may be formed to a thickness between about 10,000 Å and about 30,000 Å, and the n-type amorphous silicon layer 236 may be formed to a thickness between about 100 Å and about 500 Å.In one embodiment, the intrinsic microcrystalline silicon seed layer 233 may be formed to a thickness between about 50 Å and about 500 Å. The back contact layer 250 may include, but is not limited to, aluminum (Al), silver (Ag), titanium (Ti), chromium (Cr), gold (Au), copper (Cu), platinum (Pt), alloys thereof, or combinations thereof.

Current methods of depositing the various amorphous and microcrystalline silicon films to form the solar cell 100, 200 include introducing a mixture of hydrogen-based gas, such as hydrogen gas (H₂), and silicon-based gas, such as silane (SiH₄), into a processing region of a plasma enhanced chemical vapor deposition (PECVD) processing chamber, exciting the gas mixture to strike or form a plasma, and depositing the desired film on the substrate 102. During this process, two types of bonds are formed and deposited onto the substrate, namely Si—H bonds and Si—H₂ bonds. It has been found that the Si—H₂ bonds are undesirable because they form particles or defects in the deposited film, resulting in less efficient, lower quality bonds and film deposition. Therefore, it is desirable to increase Si—H bond formation and reduce Si—H₂ bond formation during the deposition process. Additionally, it is desirable to reduce polymerization of silicon into long chain polymers, which also results in defects formed in and instability of the deposited films. Embodiments of the present invention accomplish these results by directly introducing hydrogen radicals into the processing region of the processing chamber separately from the silicon-based gas, such that the hydrogen radicals combine with the silicon-based gas to produce significantly more Si—H bonds during the deposition process than current methods and apparatus. It is believed that the use of conventional plasma processing techniques, which use a single capacitively or inductively coupled plasma source to deliver energy to a combination of processing gases (e.g., silane and hydrogen gas) disposed in a processing region of a processing chamber, are not effective or efficient in coupling the RF power to the hydrogen atoms in the process gas mixture to create a desirable percentage of reactive hydrogen radicals to form the more desirable Si—H bonds versus the Si—H₂ bonds in the deposited silicon layer. In one example, it is believed that a single capacitively coupled plasma source, such as a RF driven showerhead disposed over a substrate, is only able to convert about 10-20% of hydrogen atoms in a silane and hydrogen gas mixture into hydrogen radicals. Therefore, by use of the combination of a capacitively or inductively coupled plasma source that delivers energy to a process gas mixture comprising hydrogen radicals delivered from a remote plasma source and a silicon-containing gas delivered from a separate gas source, the deposited film quality and electrical characteristics of the deposited film can be greatly improved. It should be noted that the term “hydrogen radical” as used herein denotes a single, highly reactive, neutral hydrogen atom.

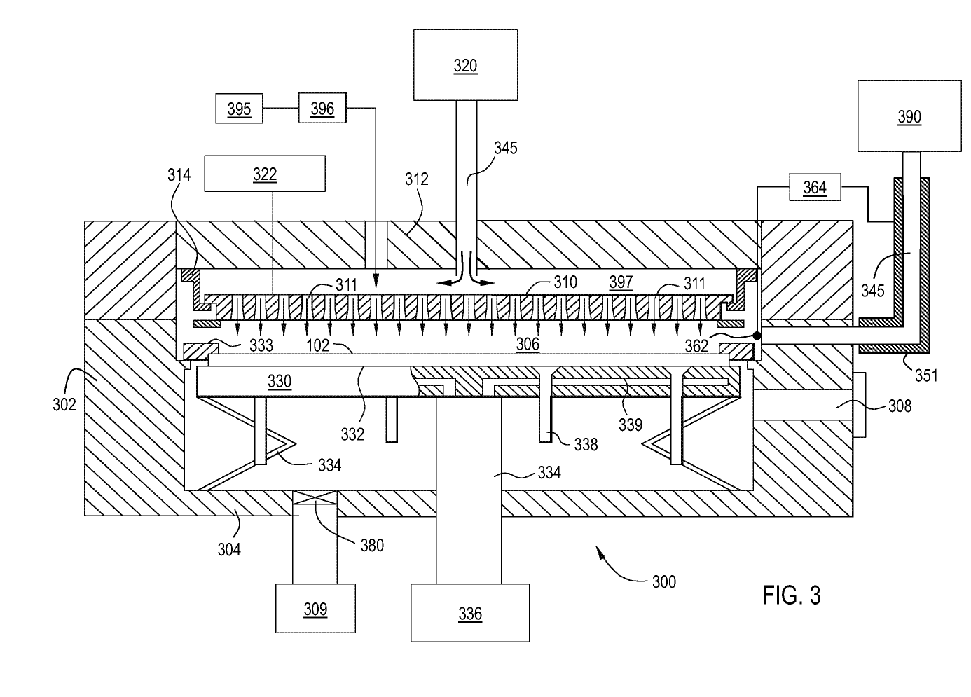

FIG. 3 is a schematic, cross-sectional view of a processing chamber 300 for depositing amorphous and microcrystalline films according to one embodiment of the present invention. In one embodiment, the chamber 300 includes walls 302, a bottom 304, a showerhead 310, and a substrate support 330, which cumulatively define a processing region 306. The processing region 306 is accessed through a valve 308, such that a substrate 102 may be transferred into and out of the chamber 300. The substrate support 330 includes a substrate receiving surface 332 for supporting the substrate 102 and stem 334 coupled to a lift system 336 configured to raise and lower the substrate support 330. A shadow frame 333 may be optionally placed over a periphery of the substrate 102. Lift pins 338 are moveably disposed through the substrate support 330 to move the substrate 102 to and from the substrate receiving surface 332. The substrate support 330 may also include heating and/or cooling elements 339 to maintain the substrate support 330 at a desired temperature. The substrate support 330 may also include grounding straps 331 to provide RF grounding at the periphery of the substrate support 330.

A hydrogen-containing gas source 390 is fluidly coupled to the processing region 306 of the processing chamber 300 through a gas conduit 345. In the embodiment shown, the gas conduit 345 is thermally coupled to a heater jacket 351. As used in this specification and the appended claims, the term “thermally coupled” means that a temperature controlling device (i.e., heater jacket 351 or cooler) can affect the temperature of the gas within the gas conduit 345. Thermal coupling can occur by convection or radiation. The hydrogen-containing gas source 390 of specific embodiments is isolated from a silicon-containing gas source 320 to prevent mixing of the hydrogen-containing gas and the silicon-containing gas outside of the processing region 306 of the processing chamber 300. Without being bound by any particular theory of operation, it is believed that the heating of the hydrogen-containing gas promotes the breakdown of high-order silanes in the plasma. Therefore, a lower amount of high-order silanes get incorporated into the film making a better quality film. Solar cells manufactured with high quality (low high-order silane concentrations) amorphous silicon films have a lower light induced degradation.

In detailed embodiments, the hydrogen-containing gas is heated from a first temperature to a second temperature. The first temperature is any temperature that the hydrogen-containing gas starts as and can be colder, isothermal or hotter than the surrounding environment. The second temperature, the temperature that the hydrogen-containing gas is heated to is greater than the first temperature. In specific embodiments, the second temperature is greater than about 100° C., 200° C., 300° C. or 400° C.

In the embodiment of FIG. 3, the gas conduit 345 is positioned to introduce the hydrogen-containing gas to the processing region 306 through the chamber wall 302. In other embodiments, the gas conduit 345 is positioned to introduce the hydrogen-containing gas to the processing region 306 via alternate routes including, but not limited to, through the showerhead 310.

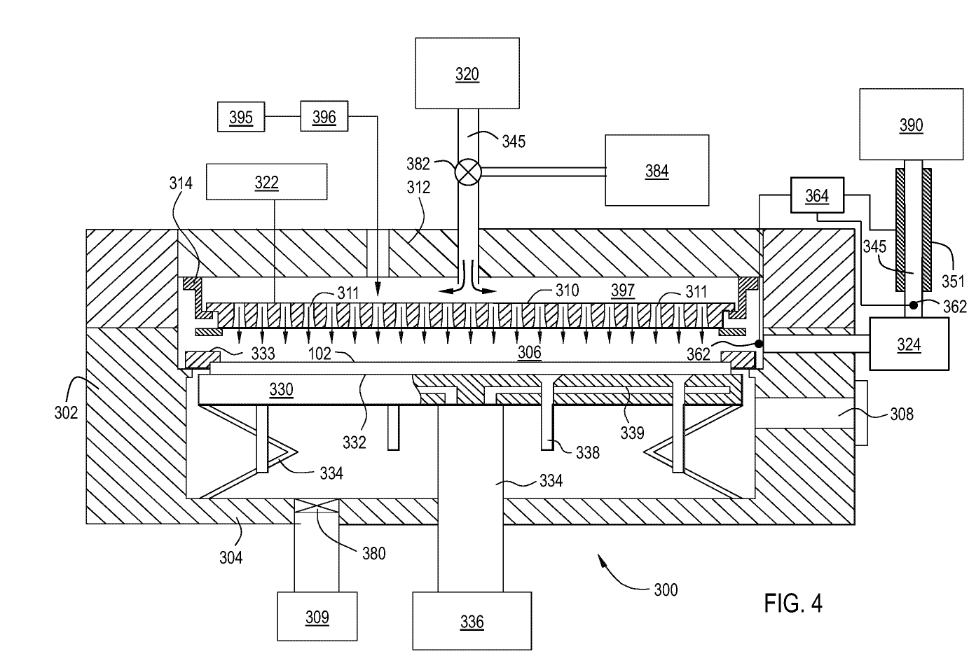

In some embodiments, an RF power source 322 is coupled to the backing plate 312 and/or to the showerhead 310 to provide an RF power to the showerhead 310 so that an electric field is created between the showerhead 310 and the substrate support 330 or chamber walls 302. Thus, the hydrogen-containing gas in the processing region 306 is energized to generate hydrogen radicals as a capacitvely coupled plasma for depositing a film on the substrate 102. A vacuum pump 309 is also coupled to the processing chamber 300 through a throttle valve 380 to control the processing region 306 at a desired pressure. In some embodiments, as described here, the hydrogen radicals are generated after the heated hydrogen-containing gas is introduced into the processing region 306 of the processing chamber 300. In alternate embodiments, as described later, the hydrogen radicals can be generated before the heated hydrogen-containing gas is introduced into the processing region 306 of the processing chamber 300. This can be done with a remote plasma source 324 (see FIG. 4 description).

In detailed embodiments, the processing chamber 300 comprises a temperature feedback circuit 364 including at least one temperature probe 362 coupled to the heater jacket 351 for monitoring the temperature of the hydrogen-containing gas entering the processing chamber 300. The heater jacket 351 can be any suitable heating mechanism capable of transferring thermal energy to the gas conduit 345. The temperature feedback circuit 364 is configured to measure the temperature of the hydrogen-containing gas and adjust the heater jacket 351, and therefore the hydrogen-containing gas, based on the measured temperature to control the hydrogen-containing gas temperature. The at least one temperature probe 362 can be placed in any suitable location. In FIG. 3, the temperature probe 362 is placed on the inside of the chamber 300 at the end of the gas conduit 345. This allows the temperature feedback circuit 364 to adjust the temperature of the heater jacket 351 so that the gas entering the chamber 300 is at a specified temperature. The location of the temperature probe 362 can be moved without deviating from the scope and spirit of the invention.

The showerhead 310 is coupled to a backing plate 312 at its periphery by a suspension 314. The showerhead 310 may also be coupled to the backing plate by one or more center supports 316 to help prevent sag and/or control the straightness/curvature of the showerhead 310. A gas source 320 is configured to supply a processing gas, such as a silicon-containing gas, through a gas conduit 345. In one embodiment, the gas conduit 345 is an annular tube configured to feed the processing gas to the processing region 306 through a plurality of gas passages 311 in the showerhead 310.

For deposition of the silicon films, a silicon-containing gas is generally provided by the gas source 320. In detailed embodiments, the silicon-containing gas is introduced into the processing chamber 300 as an unheated gas. As used in this specification and the appended claims, the term “unheated” means that the gas is at the temperature of the surrounding environment. This environment can be the room where the gas is stored, or the tubes that the gas pass through or the body of the processing chamber 300. In specific embodiments, the silicon-containing gas has a temperature lower than the ambient environment. Suitable silicon-containing gases include, but are not limited to silane (SiH₄), disilane (Si₂H₆), silicon tetrafluoride (SiF₄), silicon tetrachloride (SiCl₄), dichlorosilane (SiH₂Cl₂), and combinations thereof. In specific embodiments, the silicon-containing gas is silane.

In some embodiments, the processing chamber 300 also includes a cleaning gas remote plasma source 395 that is fluidly coupled to a gas plenum 397, located behind the showerhead 310, and further coupled to the processing region 306 through the gas passages 311 formed in the showerhead 310. The cleaning gas remote plasma source 395 is coupled to a cleaning gas source 396 that is able to deliver a cleaning gas to the cleaning gas remote plasma source 395 so that energetic cleaning gases can be formed to clean the surfaces of the showerhead 310 and other chamber components between deposition processes. Typical cleaning gases include halogen-containing gases, such as N_{F3, F2}, C₁₂, or other gases which are used to remove portions of deposited material formed on chamber components during prior deposition processes.

FIG. 4 shows another embodiment of the invention where the processing chamber 300 further comprises a remote plasma source 324 in fluid communication with the gas conduit 345. The remote plasma source 324 is suitable for generating hydrogen radicals in the hydrogen-containing gas. The remote plasma source 324 is shown downstream of the heater jacket 351, but can be located upstream of the heater jacket 351. Placing the remote plasma source 324 downstream of the heater ensures that the hydrogen-containing gas is hot prior to generating hydrogen radicals and introduction of said radicals to the processing region 306 of the processing chamber 300.

The embodiment shown in FIG. 4 has two temperature probes 362. One probe is located downstream of the heater jacket 351 and the second is inside the chamber 300, downstream of the remote plasma source 324. This configuration would allow for the measurement of the temperature of the hydrogen-containing gas before and after radical generation. The dual probe configuration shown is merely illustrative of an example temperature feedback circuit 364 and should not be taken as limiting the scope of the invention. In specific embodiments, a single temperature probe 362 is used downstream of the heater jacket 351 before the gas enters the remote plasma source 324.

Detailed embodiments of the invention further comprise at least one supplemental processing gas source 384 coupled to the processing region 306 of the processing chamber 300. The at least one supplemental processing gas source 384 can be coupled to the processing region 306 through the plurality of gas passages 311 in the showerhead 310. In specific embodiments, a proportioning valve 382 connects the supplemental processing gas source 384 to the silicon-containing gas source 320. This proportioning valve 382 isolates and mixes the silicon-containing gas from the at least one supplemental processing gas prior to introduction into the processing region 306.

In p-type layers, the p-type dopants may each comprise a group III element, such as boron or aluminum. Examples of boron-containing sources include trimethylboron (TMB), diborane (B₂H₆), and similar compounds. In n-type layers, the n-type dopants may each comprise a group V element, such as phosphorus, arsenic, or antimony. Examples of phosphorus-containing sources include phosphine and similar compounds. The dopants are typically provided with a carrier gas, such as hydrogen, argon, helium, and other suitable compounds. In detailed embodiments the at least one supplemental processing gas source 384 comprises one or more of trimethylboron (TMB), methane and phosphine.

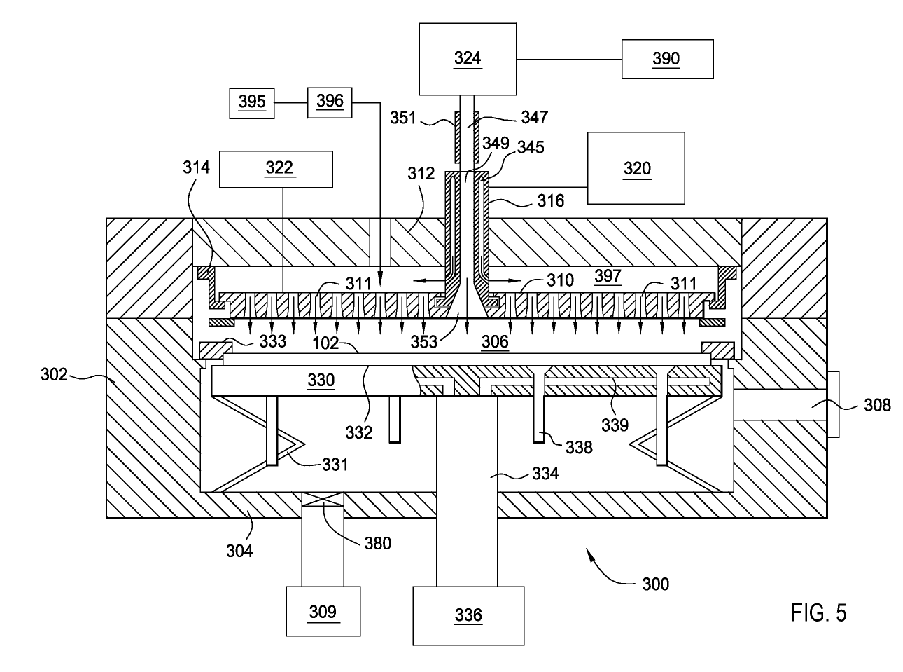

FIG. 5 shows another embodiment of the invention in which the showerhead 310 is coupled to the backing plate 312 by one or more center supports 316 to help prevent sag and/or control the straightness/curvature of the showerhead 310.

The hydrogen gas source 390 of FIG. 5 is fluidly coupled to a remote plasma source 324, such as an inductively coupled remote plasma source. The remote plasma source 324 is also fluidly coupled to the processing region 306 through line of sight tubing 347 and a central gas conduit 349. The line of sight tubing 347 fluidly couples the remote plasma source 324 to the central gas conduit 349. The term “line of sight” used herein is meant to convey a short distance between the remote plasma source 324 and the processing chamber 300 so as to minimize the possibility of hydrogen radical recombination or adsorption onto the surface of the tubing. In one embodiment, the line of sight tubing 347 provides a direct path for the hydrogen radicals without any sharp bends therein. In one embodiment, the line of sight tubing 347 provides a direct path for the hydrogen radicals without any bends therein. The line of sight tubing 347 comprises tubing made of an inert material, such as sapphire, quartz, or other ceramic material, to prevent adsorption and/or recombination of the hydrogen radicals provided by the remote plasma source 324. Additionally, a heater jacket 351 may be provided to further prevent adsorption and/or recombination of the hydrogen radicals provided by the remote plasma source 324 prior to their delivery into the processing region 306. The line of sight tubing 347 and the central gas conduit 349 are configured to provide a direct, short path for hydrogen radicals generated in the remote plasma source 324 into the processing region 306. In one embodiment, the central gas conduit 349 is configured to directly feed hydrogen radicals generated in the remote plasma source 324 through a central opening 353 in the showerhead 310 into the processing region 306.

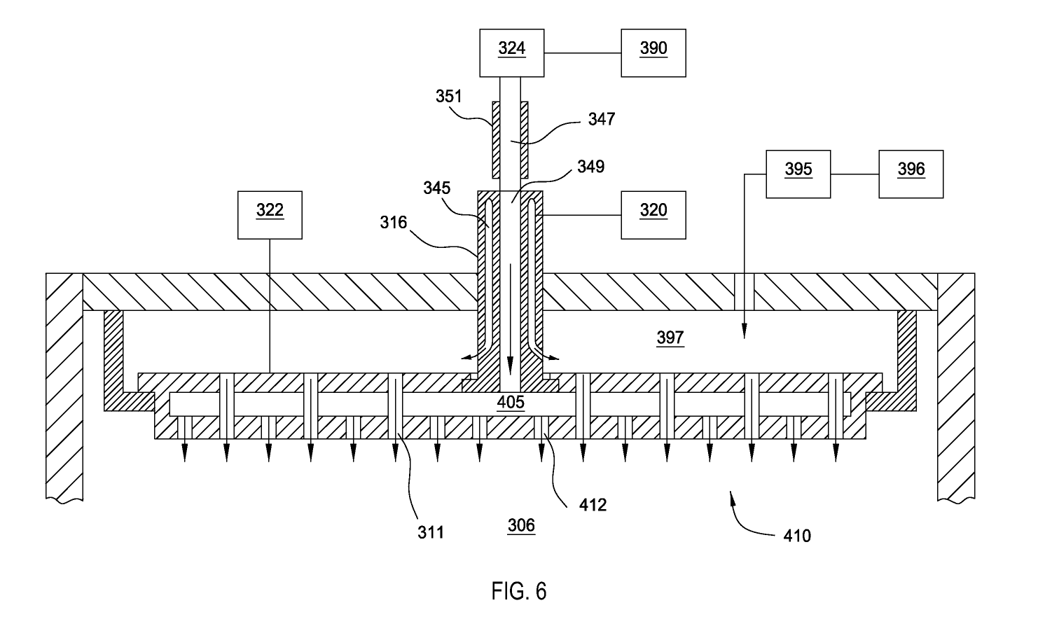

FIG. 6 is a schematic, cross-sectional view of a showerhead 410 for separately delivering hydrogen radicals from the remote plasma source 324 and a process gas from the processing gas source 320 into the processing region 306 of the processing chamber 300 according to another embodiment. In this embodiment, the central gas conduit 349 is fluidly coupled to an interior region 405 within the showerhead 410. The interior region 405 is, in turn, fluidly coupled to a plurality of passages 412 fluidly connecting the interior region 405 of the showerhead 410 to the processing region 306 of the processing chamber 300. In this configuration, the hydrogen radicals are delivered from the remote plasma source 324, through the line of sight tubing 347 and the central gas conduit 349 into the interior region 405 of the showerhead 410. From there, the hydrogen radicals are evenly distributed into the processing region 306 through the plurality of passages 412. Simultaneously, a processing gas, such as silane, is delivered from the gas source 320, through the gas conduit 345, and through the plurality of gas passages 311 in the showerhead 410 into the processing region 306.

Regardless of the specific embodiment, the gas source 320, remote plasma source 324, and the showerhead 310, 410 are configured such that hydrogen radicals generated in the remote plasma source 324 are introduced to the processing gas only within the processing region 306 in order to prevent undesirable mixing and undesirable deposition in other regions of the processing chamber 300. Further, the hydrogen radicals are delivered directly into the processing region 306 to minimize recombination or energy loss by the hydrogen atoms prior to mixing with the processing gas(es) disposed in the processing region 306. Thus, undesirable the undesirable Si—H₂ bonds are minimized and the desirable Si—H bonds are maximized to provide better more efficient silicon film deposition.

In one embodiment, the heating and/or cooling elements 339 are set to provide a substrate support temperature during deposition of about 400° C. or less, preferably between about 150° C. and about 400° C. The spacing during deposition between the top surface of the substrate 102 disposed on the substrate receiving surface 332 and the showerhead 310, 410 may be between about 200 mil and about 1,000 mil.

The following illustrates an example of a processing sequence that may be used to form a tandem cell, such as the solar cell 200 illustrated in FIG. 2, in one or more processing chambers 300, shown in FIGS. 3 through 6, according to embodiments of the present invention. In one embodiment, a substrate 102 having a front TCO layer 110 deposited thereon is received into one processing chamber 300. A p-type amorphous silicon layer 122 may be formed on the substrate 102 by providing silane gas at a flow rate between about 1 sccm/L and about 10 sccm/L from the gas source 320, through the gas conduit 345, and through the plurality of gas passages 311 in the showerhead 310, 410 into the processing region 306. Simultaneously, hydrogen radicals, generated in the remote plasma source 324 according to the description provided above, are provided through the line of sight tubing 347, the central gas conduit 349, and the showerhead 310, 410 into the processing region 306. Trimethylboron may be provided with the silane at a flow rate between about 0.005 sccm/L and bout 0.05 sccm/L. Methane may also be provided at a flow rate between about 1 sccm/L and about 15 sccm/L. An RF power between about 15 mW/cm² and about 200 mW/cm² may be provided to the showerhead 310, 410 to form a plasma in the processing region 306 (FIG. 5) over the surface of the substrate 102. The formed plasma over the substrate 102 comprises the silane gas delivered through the showerhead 310, 410 and the hydrogen radicals delivered from the remote plasma source 324. The pressure of the processing chamber 300 may be maintained between about 0.1 Torr and about 20 Torr, preferably between about 1 Torr and about 4 Torr.

Next, the substrate 102 may be transferred into another processing chamber, which is similarly configured to the processing chamber 300, for deposition of an intrinsic type amorphous silicon layer 124 over the p-type amorphous silicon layer 122. In one embodiment, silane gas is provided at a flow rate between about 0.5 sccm/L and about 7 sccm/L from the gas source 320, through the gas conduit 345, and through the plurality of gas passages 311 in the showerhead 310, 410 into the processing region 306. Simultaneously, hydrogen radicals, generated in the remote plasma source 324 according to the description provided above, are provided through the line of sight tubing 347, the central gas conduit 349, and the showerhead 310, 410 into the processing region 306. An RF power between about 15 mW/cm² and about 250 mW/cm² may be provided to the showerhead 310, 410 to deliver energy to the silane and the hydrogen radical mixture in the processing region 306. The pressure of the processing chamber 300 may be between about 0.5 Torr and about 5 Torr.

Next, while the substrate 102 is still in the processing chamber 300, an n-type microcrystalline silicon layer 126 is deposited on the intrinsic type amorphous silicon layer 124. In one embodiment, silane gas is provided at a flow rate between about 0.1 sccm/L and about 0.8 sccm/L, such as about 0.35 sccm/L from the gas source 320, through the gas conduit 345, and through the plurality of gas passages 311 in the showerhead 310, 410 into the processing region 306. Simultaneously, hydrogen radicals, generated in the remote plasma source 324 according to the description provided above, are provided through the line of sight tubing 347, the central gas conduit 349, and the showerhead 310, 410 into the processing region 306. Phosphine may be provided with the silane at a flow rate between about 0.0005 sccm/L and about 0.06 sccm/L. An RF power between about 100 mW/cm² and about 900 mW/cm² may be provided to the showerhead 310, 410 to deliver energy to the silane and the hydrogen radical mixture in the processing region 306. The pressure of the processing chamber 300 may be between about 1 Torr and about 100 Torr, preferably between about 3 Torr and about 20 Torr.

Next, the substrate 102 is moved to another processing chamber 300 for depositing a p-type microcrystalline silicon layer 132 over the n-type microcrystalline silicon layer 126. In one embodiment, silane gas is provided at a flow rate between about 0.1 sccm/L and about 0.8 sccm/L from the gas source 320, through the gas conduit 345, and through the plurality of gas passages 311 in the showerhead 310, 410 into the processing region 306. Simultaneously, hydrogen radicals, generated in the remote plasma source 324 according to the description provided above with, are provided through the line of sight tubing 347, the central gas conduit 349, and the showerhead 310, 410 into the processing region 306. Trimethylboron may be provided along with the silane at a flow rate between about 0.0002 sccm/L and about 0.0016 sccm/L. An RF power between about 50 mW/cm² and about 700 mW/cm² may be provided to the showerhead 310, 410 to deliver energy to the silane and the hydrogen radical mixture in the processing region 306. The pressure of the processing chamber 300 may be between about 1 Torr and about 100 Torr, preferably between about 3 Torr and about 20 Torr.

Next, the substrate 102 is transferred into another processing chamber 300 for deposition of the intrinsic type microcrystalline silicon seed layer 133 over the p-type microcrystalline silicon layer 132. In one embodiment, silane gas is gradually ramped up from a zero point to a second set point, such as between about 2.8 sccm/L and about 5.6 sccm/L over a time period from about 20 seconds to about 300 seconds, such as between about 40 seconds and about 240 seconds. The ramped up silane flow is provided from the gas source 320, through the gas conduit 345, and through the plurality of gas passages 311 in the showerhead 310, 410 into the processing region 306. Simultaneously, hydrogen radicals, generated in the remote plasma source 324 according to the description provided above, are provided through the line of sight tubing 347, the central gas conduit 349, and the showerhead 310, 410 into the processing region 306. An RF power may also be ramped up similarly to the silane flow from about 0 Watts to about 2 Watts/cm² to deliver energy to the silane and the hydrogen radical mixture in the processing region 306. The pressure of the processing chamber 300 may be between about 1 Tor and about 12 Torr.

It is believed that the gradual ramp-up of the silane gas flow in the intrinsic type microcrystalline silicon seed layer 133 formation assists silicon atoms in uniformly adhering and distributing on the surface of the substrate 102, thereby forming the intrinsic type microcrystalline silicon seed layer 133 with desirable film properties. Uniform adherence of the silicon atoms on the surface of the substrate 102 provides good nucleation sites for subsequent atoms to nucleate thereon. Uniform nucleation sites formed on the substrate 102 promote crystallinity of films subsequently formed thereon. Therefore, the gradual ramp-up of the silane flow into the processing region 306 allows the dissociated silicon atoms to have sufficient time to be gradually absorbed on the surface of the substrate 102, thereby providing a surface having an even distribution of silicon atoms that provides nucleation sites, which promote improved crystallinity of subsequently deposited layers.

Next, an intrinsic type microcrystalline silicon layer 134 is deposited over the intrinsic type microcrystalline silicon seed layer 133 in the processing chamber 300. Silane gas may be provided at a flow rate between about 0.5 sccm/L and about 5 sccm/L from the gas source 320, through the gas conduit 345, and through the plurality of gas passages 311 in the showerhead 310, 410 into the processing region 306. Simultaneously, hydrogen radicals, generated in the remote plasma source 324 according to the description provided above, are provided through the line of sight tubing 347, the central gas conduit 349, and the showerhead 310, 410 into the processing region 306. An RF power between about 300 mW/cm² or greater, preferably 600 mW/cm² or greater, may be provided to the showerhead 310, 410 to deliver energy to the silane and the hydrogen radical mixture in the processing region 306. The pressure of the processing chamber 300 may be between about 1 Torr and about 100 Torr, preferably between about 3 Torr and about 20 Torr.

Finally, while the substrate is still positioned in the processing chamber 300, an n-type amorphous silicon layer 126 is deposited over the intrinsic type microcrystalline silicon layer 126 on the substrate 201. In one embodiment, the n-type amorphous silicon layer 136 may be deposited by first depositing an optional first n-type amorphous silicon layer at a first silane flow rate and then depositing a second n-type amorphous silicon layer over the first optional n-type amorphous silicon layer at a second silane flow rate lower than the first silane flow rate. The first optional n-type amorphous silicon layer may be deposited by providing silane gas at a flow rate between about 1 sccm/L and about 10 sccm/L, such as about 5.5 sccm/L from the gas source 320, through the gas conduit 345, and through the plurality of gas passages 311 in the showerhead 310, 410 into the processing region 306. Simultaneously, hydrogen radicals, generated in the remote plasma source 324 according to the description provided above, are provided through the line of sight tubing 347, the central gas conduit 349, and the showerhead 310, 410 into the processing region 306. Phosphine may be provided at a flow rate between about 0.0005 sccm/L and about 0.0015 sccm/L, such as about 0.0095 sccm/L along with the silane. An RF power between about 25 mW/cm² and about 250 mW/cm² may be provided to the showerhead 310, 410 to deliver energy to the silane and the hydrogen radical mixture in the processing region 306. The pressure of the processing chamber 300 may be between about 0.1 Torr and about 20 Torr, preferably between about 0.5 Torr and about 4 Torr.

The second n-type amorphous silicon layer deposition may comprise providing silane gas at a flow rate between about 0.1 sccm/L and about 5 sccm/L, such as about 0.5 sccm/L and about 3 sccm/L, for example about 1.42 sccm/L from the gas source 320, through the gas conduit 345, and through the plurality of gas passages 311 in the showerhead 310, 410 into the processing region 306. Simultaneously, hydrogen radicals, generated in the remote plasma source 324 according to the description provided above, are provided through the line of sight tubing 347, the central gas conduit 349, and the showerhead 310, 410 into the processing region 306. Phosphine may be provided at a flow rate between about 0.01 sccm/L and about 0.075 sccm/L, such as between about 0.015 sccm/L and about 0.03 sccm/L, for example about 0.023 sccm/L. An RF power between about 25 mW/cm² and about 250 mW/cm², such as about 60 mW/cm² may be provided to the showerhead 310, 410 to deliver energy to the silane and the hydrogen radical mixture in the processing region 306. The pressure of the processing chamber 300 may be between about 0.1 Torr and about 20 Torr, such as between about 0.5 Torr and about 4 Torr, for example about 1.5 Torr.

Thus, each of the silicon-containing layers in a solar cell may be provided by generating hydrogen radicals in a remote plasma source and delivering the hydrogen radicals directly into the processing region of the processing chamber to combine with the silicon-containing gas according to embodiments of the present invention. Directly providing the hydrogen radicals into the processing region for reaction with the silicon-containing gas results in improved bonding structure, deposition efficiency, and deposited film stability over prior art deposition methods.

In alternative embodiments to each of the preceding steps, the hydrogen radicals can be generated in the processing region 306 of the processing chamber 300. A heated hydrogen-containing gas can be introduced into the processing region 306 either through an isolated gas conduits 345 that passes through the chamber wall 302 (as shown in FIGS. 3 and 4) or through a gas conduit 345 that passes through the showerhead 310 (as shown in FIGS. 5 and 6). The heated hydrogen can then be energized to strike a plasma using the RF power source 322. Once the plasma has been generated in the processing region 306, the silicon-containing gas can be added to the processing region 306. Additionally, as shown in the embodiment of FIG. 4, the heated hydrogen-containing gas can be energized to ignite a plasma prior to introduction into the processing region 306 through the chamber wall 302.

Although the invention herein has been described with reference to particular embodiments, it is to be understood that these embodiments are merely illustrative of the principles and applications of the present invention. It will be apparent to those skilled in the art that various modifications and variations can be made to the method of the present invention without departing from the spirit and scope of the invention. Thus, it is intended that the present invention include modifications and variations that are within the scope of the appended claims and their equivalents.

What is claimed is:

1. A method for depositing a silicon film on a substrate, comprising:
heating a hydrogen-containing gas;
delivering the heated hydrogen-containing gas into a plasma generation region to energize the hydrogen-containing gas to generate hydrogen radicals for use in a processing region of a processing chamber, the processing region being defined as a space between a showerhead, the substrate and walls of the processing chamber; and
introducing a silicon-containing gas into the processing region of the processing chamber separate from the hydrogen-containing gas to prevent mixing with the hydrogen radicals outside of the processing region of the processing chamber.

2. The method of claim 1, wherein the plasma generation region is in the processing region of the chamber.

3. The method of claim 1, wherein the plasma generation region is remote from and in fluid communication with the processing region of the chamber.

4. The method of claim 1, further comprising monitoring the temperature of the hydrogen-containing gas.

5. The method of claim 4, further comprising heating the hydrogen-containing gas a different rate.

6. The method of claim 1, wherein the processing region includes a substrate support.

7. The method of claim 6, further comprising delivering the silicon-containing gas from a gas source to the processing region via a plurality of gas passages within the showerhead.

8. The method of claim 7, wherein the hydrogen-containing gas or hydrogen radicals are introduced to the processing region of the processing chamber through a central opening in the showerhead, the central opening being isolated from the plurality of gas passages.

9. The method of claim 1, wherein the hydrogen-containing gas or hydrogen radicals are introduced to the processing region of the processing chamber through an isolated line passing through the walls of the processing chamber.

10. The method of claim 1, further comprising introducing one or more of trimethylboron (TMB), methane and phosphine to the processing region of the processing chamber.

11. An apparatus for depositing a silicon film, comprising:
a processing chamber having a plurality of walls, a showerhead, and a substrate support defining a processing region within the processing chamber, the showerhead comprising a plurality of gas passages;
a silicon-containing gas source coupled to the processing region through the plurality of gas passages; and
a hydrogen-containing gas source coupled to the processing region through a gas conduit, the gas conduit thermally coupled to a heater to increase the temperature of the hydrogen-containing gas, the hydrogen-containing gas source isolated from the silicon-containing gas source to prevent mixing of the hydrogen-containing gas and the silicon-containing gas outside of the processing region.

12. The apparatus of claim 11, further comprising a remote plasma source in fluid communication with the gas conduit and downstream from the heater, the remote plasma source operable to generate hydrogen radicals in the hydrogen-containing gas prior to introduction of the hydrogen-containing gas to the processing region.

13. The apparatus of claim 12, wherein the gas conduit is positioned to introduce the hydrogen-containing gas to the processing region through the chamber wall.

14. The apparatus of claim 12, wherein the showerhead has a central opening in fluid communication with the gas conduit.

15. The apparatus of claim 11, further comprising at least one supplemental processing gas source coupled to the processing region of the processing chamber.

16. The apparatus of claim 15, wherein the at least one supplemental processing gas source comprises one or more of trimethylboron (TMB), methane and phosphine.

17. The apparatus of claim 15, wherein the at least one supplemental processing gas source is coupled to the processing region through the plurality of gas passages in the showerhead.

18. The apparatus of claim 17, further comprising a proportioning valve to isolate and mix the silicon-containing gas from the at least one supplemental processing gas.

19. The apparatus of claim 11, further comprising a temperature feedback circuit including a temperature probe coupled to the heater, the temperature feedback circuit configured to measure the temperature of the hydrogen-containing gas and adjust the heater based on the measured temperature to control the hydrogen-containing gas temperature.
